(19) United States
(12) Patent Application Publication
(10) Pub. No.: US 2026/0073104 A1
(43) Pub. Date: Mar. 12, 2026

(54) CHIPLET OPTIMIZATION TOOL KIT

(71) Applicant: Advanced Micro Devices, Inc., Santa Clara, CA (US)

(72) Inventors: Garrett Jamison WYATT, Phoenix, AZ (US); Deepak Vasant KULKARNI, Austin, TX (US); Siddhartha SAXENA, Santa Clara, CA (US); Tanmay Kamalakar MUDHOLKAR, Austin, TX (US); Nikhil Kumar Reddy OBILI, Austin, TX (US)

(21) Appl. No.: 18/826,734

(22) Filed: Sep. 6, 2024

(51) Int. Cl. G06F 30/31; G06F 30/392

(52) U.S. Cl. CPC G06F 30/31; G06F 30/392

(57) ABSTRACT

Embodiments herein describe a method including receiving an initial chiplet layout, determining chiplet size for improving mask field utilization (MFU) using a plurality of first parameters, determining chiplet placement for improving gross modules per wafer (GMPW) using a plurality of second parameters, and generating an updated chiplet floorplan based on the determined chiplet size and the determined chiplet placement. Machine learning (ML) models are used to generate the optimized updated chiplet floorplan.

### TECHNICAL FIELD

Examples of the present disclosure generally relate to advanced packing technologies, and, in particular, to a chiplet optimization tool kit.

### BACKGROUND

Integrated circuit (IC) packaging is the process of enclosing and protecting IC chips to ensure their mechanical and environmental stability. Advanced packaging may be employed to aggregate components from various wafers, creating a single electronic device with superior performance. Advanced packaging techniques that have arisen lately include 2.5D, 3D, fan-out, and system-on-a-chip (SoC) packaging, which supplement wire-bonding and flip-chip technologies.

### SUMMARY

One embodiment described herein is an advanced packaging floorplan configured through the methodology described. Starting from an initial chiplet layout floorplan, an optimized chiplet size is produced by maximizing the mask field utilization (MFU) using a plurality of first parameters, and an optimized chiplet placement is determined for maximizing gross modules per wafer (GMPW) using a plurality of second parameters.

One embodiment described herein is a system including at least one physical processor and physical memory including computer-executable instructions that, when executed by the physical processor, cause the physical processor to receive an initial chiplet layout, determine chiplet size for improving mask field utilization (MFU) using a plurality of first parameters, determine chiplet placement for improving gross modules per wafer (GMPW) using a plurality of second parameters, and generate an updated chiplet floorplan based on the determined chiplet size and the determined chiplet placement.

One embodiment described herein is a non-transitory computer-readable medium storing instructions that, when executed by a processor, cause the processor to receive an initial chiplet layout, determine chiplet size for improving mask field utilization (MFU) using the plurality of first parameters, determine chiplet placement for improving gross modules per wafer (GMPW) using the plurality of second parameters, and generate an updated chiplet floorplan based on the determined chiplet size and the determined chiplet placement.

One embodiment described herein is a method including receiving an initial chiplet layout, determining chiplet size for improving mask field utilization (MFU) using a plurality of first parameters, determining chiplet placement for improving gross modules per wafer (GMPW) using a plurality of second parameters, and generating an updated chiplet floorplan based on the determined chiplet size and the determined chiplet placement.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1A illustrates a cross-sectional view of an advanced package including chiplets, a chip module, a bridge, and a substrate, according to an example.

FIG. 1B illustrates top view floorplan of the advanced package of FIG. 1, according to an example.

FIG. 2 illustrates a high-level schematic of the chiplet optimization tool, according to an example.

FIG. 3 illustrates how optimizing a chiplet layout produces cost savings, according to an example.

FIG. 4 illustrates interoperability of the chiplet optimization tool, according to an example.

FIG. 5 illustrates a block diagram of the features of the chiplet optimization tool, according to an example.

FIG. 6 illustrates a user interface for implementing the chiplet optimization tool, according to an example.

FIG. 7 illustrates a method for implementing the chiplet optimization tool, according to an example.

FIG. 8 illustrates a process for generating an optimized floorplan based on optimal chiplet size and optimal module size.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the embodiments herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Semiconductor design is going through a transformation as Moore's law declines and the scaling of compute power loses its parabolic rise. To combat this decline, designers rely on new advancements in chiplet and package design to sustain compute scaling and continue to optimize performance, efficiency, and cost. A chiplet is a hard IP piece of silicon that can be connected through the silicon package to other chiplets. The reduction in size requirements, as compared to monolithic designs, results in higher manufacturing yield and design re-usability. A silicon package is the container that holds the monolithic or chiplet dies and drives the overall performance, efficiency, and cost of a design. Package design is becoming more advanced with the proliferation of chiplet designs, as various package architectures can be deployed to stich the various chiplets back together while balancing competing variables. The set of packaging solutions leveraging 2.5/3D architectures is normally referred to as advanced packaging and includes multiple tiers of components.

Advanced packing allows multiple devices, including electrical, mechanical, or semiconductor devices, to be merged and packaged as a single electronic device. Advanced packaging can help achieve performance gains through the integration of several devices in one package and associated efficiency gains (by reducing the distances signals have to travel, and thus reducing signal paths), and allowing for high numbers of connections between devices, without having to resort to smaller transistors, which have become increasingly more difficult to manufacture. However, such gains may not be obtained for monolithic designs, which may outperform chiplet designs. Advanced packaging involves using chip modules and chiplets to enhance performance, reduce costs, and improve power efficiency.

Calculating the optimal size for chiplets and chip modules involves balancing several factors including performance, power efficiency, manufacturing yields, and cost. Performance requirements include taking into account workload analysis, latency, and bandwidth requirements. Power efficiency includes taking into account power budgets and thermal management requirements. Manufacturing considerations include taking into account yield, defects, and different process technologies. Further, cost analysis takes into consideration fabrication costs, as well as assembly and packaging costs.

For example, regarding cost, adding as little as a 100 μm to a given die size can increase the overall module size enough to add multiple dollars to a packaging solution. To illustrate the point, if it is assumed that roughly 10 million central processing units (CPUs) sold inside a gaming unit in 2023, and $5.00 is added to the packaging cost, that translates to a $50 million dollar hit to gross margins. Therefore, ensuring that the absolute best floorplan is architected will lead to a high return on investment. Selecting this floorplan is not a simple task, as it involves solving a complex multi-variable optimization problem.

The example embodiments disclose a novel mechanism to assist in the resolution of competing variables by calculating the optimal chiplet size and the optimal chip module size, also known as a floorplan, of a 2.5D/3D advanced packaging solution. The novel mechanism involves using a chiplet optimization tool kit that will take a target starting design and then use artificial intelligence/machine learning (AI/ML) models to find an optimized system floorplan that includes the top dies, chip module, bridges, and substrate. This is achieved by balancing the variables that lead to the best overall design when considering, e.g., die reticle size, chiplet module size, and gross modules per wafer. The example embodiments present a methodology for training the model by leveraging Advanced Micro Devices (AMD) or company-specific design rules, leveraging electronic computer-aided design (ECAD) tools to reduce the boundary condition complexity, an automated technology file generator, a front-end user interface to interact with the model, and unique variable weightings from company-specific training data. As such, the chiplet optimization tool kit takes the manual process of selecting optimal package floorplans and recommends the best choices based on a trained model that optimizes trade-offs between die reticle size, gross modules per wafer, and chip module size.

Therefore, the example embodiments provide for a chiplet optimization tool driven by AI/MI models or algorithms to produce optimized chiplet layouts. The novel features include at least providing a bridge between the ECAD and the AI/ML model, accepting boundary conditions specific to a design de-coupled from the AI model and AI training, using an AI model trained on a proprietary database populated with data gathered by AMD, a user interface for capturing the relevant die attribute data, and a weight function or training weights assigned to the modified objective function as the AI model creates the optimized floorplan.

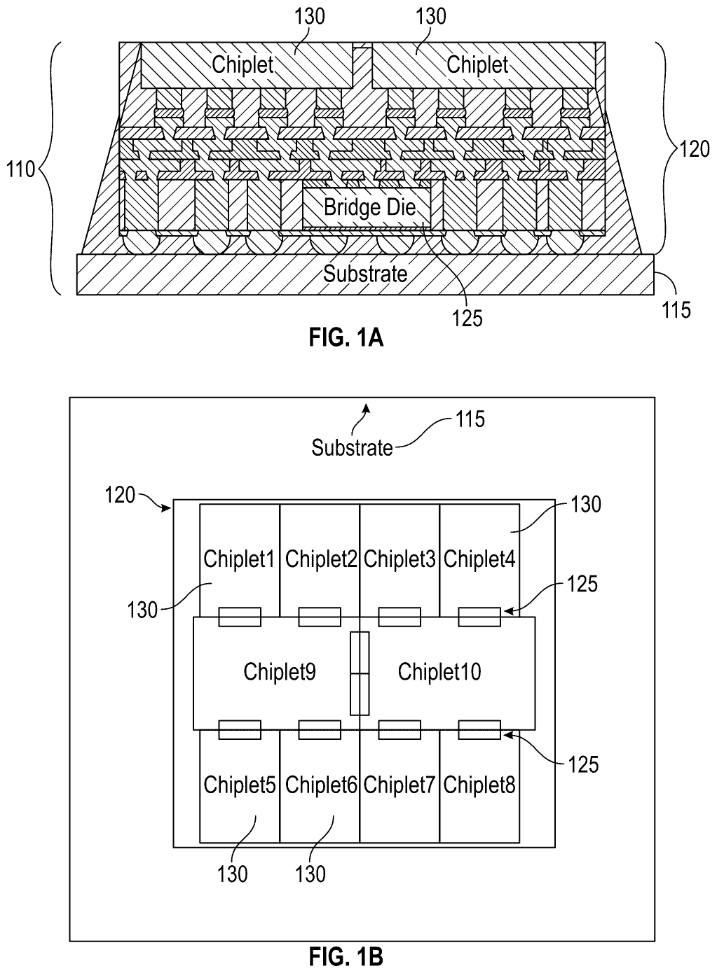

FIG. 1A illustrates a cross-sectional view of an advanced package including chiplets, a chip module, a bridge, and a substrate, according to an example.

The cross-sectional view of the advanced package 110 includes a chip module 120 disposed over a substrate 115. The chip module 120 may include a bridge die 125. Chiplets 130 may be electrically coupled to the chip module 120 via multiple tiers of components. These tiers of components range from top chiplet dies that can be stacked or non-stacked, chip modules, embedded silicon bridges to allow for communication between top dies, and substrates. Attributes of each of these components, such as fit, form, and function, are heavily dependent on each other when trying to create an optimal floorplan within a given advanced packaging architecture.

The chiplets 130 are small integrated circuits (ICs) that form part of a larger chip system. Unlike traditional monolithic chip designs, where all components are built into a single, large piece of silicon, chiplets 130 are modular and can be combined to create a more complex processor. This approach allows for greater flexibility and efficiency in chip design and manufacturing. The chiplets 130 can be designed and fabricated independently and then combined to form a complete system. This modularity allows for customization and scalability. Producing smaller chiplets can reduce manufacturing defects and improve yields compared to creating a large monolithic chip. Since different parts of the chip can be manufactured separately, it reduces the cost associated with producing large, complex chips. It also allows manufacturers to mix and match the chiplets 130 from different production batches. Moreover, optimizing the chiplet floorplan can help optimize performance, power, and area (PPA).

FIG. 1B illustrates top view floorplan of the advanced package of FIG. 1, according to an example.

The chiplet floorplan depicts the chip module 120 including a plurality of chiplets 130. The chiplet floorplan involves carefully arranging the plurality of chiplets 130 within a single package to optimize PPA. A bridge die 125 may be used to couple the chiplets 130 together over the substrate 115.

In 2.5D packaging, multiple chiplets are placed side by side on an interposer, which provides the interconnections between them. The interposer is a thin piece of silicon or organic material that facilitates high-bandwidth communication. Thus, in 2.5D packaging, the main components may include chiplets, an interposer, a packaging substrate, and microbumps to couple the chiplets to the interposer. In 2.5D packaging, the floorplan is constructed by defining the chiplet functions, arranging the chiplets on the interposer to minimize critical path lengths and optimize signal integrity, designing the routing on the interposer to ensure efficient data transfer between chiplets, and considering the thermal profile of the arrangement (i.e., thermal management).

In 3D packaging, multiple dies are stacked vertically, enabling higher density and shorter interconnects compared to 2.5D packaging. In 3D packaging, the main components include stacked dies, through-silicon vias (TSVs), microbumps/bumps, and the package substrate. In 3D packaging, the floorplan is constructed by defining the stack layers, performing vertical placement, designing the placement of the TSVs to ensure efficient communication between the layers, and considering the thermal profile to address thermal challenges by placing high-power dies in positions that facilitate heat removal.

By carefully designing the floorplan of 2.5D and 3D advanced packaging solutions, engineers can create high-performance, power-efficient, and compact semiconductor packages suitable for a wide range of applications.

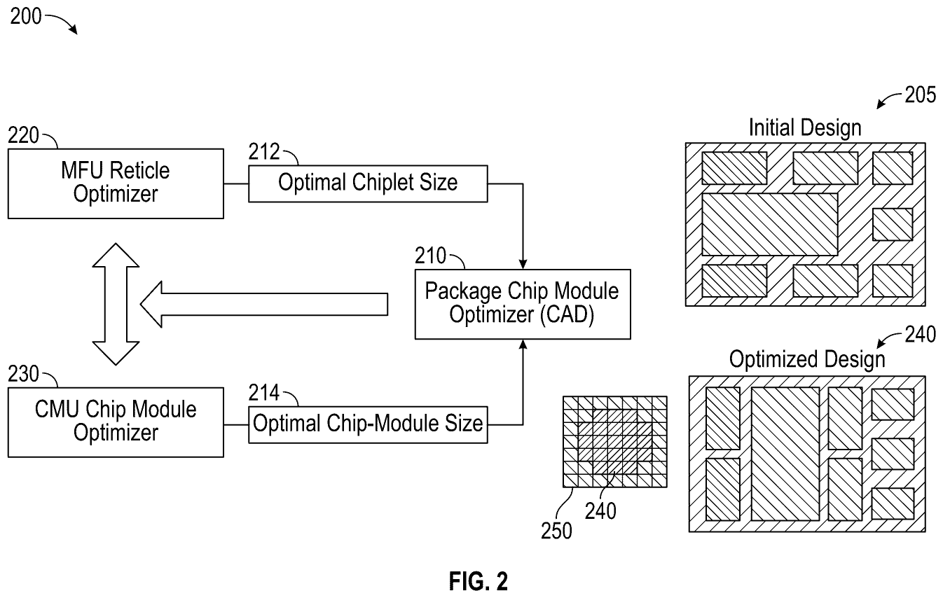

FIG. 2 illustrates a high-level schematic of the chiplet optimization tool, according to an example.

The chiplet optimization tool kit 200 takes an initial design 205 and feeds it into a package chip module optimizer 210. The package chip module optimizer 210 is a tool used in the design and optimization of semiconductor packages that integrate multiple chiplets or components into a single module. The primary goal of the package chip module optimizer 210 is to enhance the overall performance, power, efficiency, area utilization, and thermal management of the package. The package chip module optimizer 210 generates an optimal chiplet size 212 and an optimal chip module size 214. The package chip module optimizer 210 may communicate with one or more processors or microprocessors for generating an optimal chiplet size 212 and for generating an optimal chip module size 214.

The optimal chiplet size 212 is generated using, e.g., a mask field utilization (MFU) reticle optimizer 220. The MFU reticle optimizer 220 is a tool used in the semiconductor manufacturing process to optimize the layout of multiple chip designs on a single photomask, also referred to as a reticle. This optimization process is beneficial for maximizing the efficiency and flexibility of semiconductor fabrication. The main functions of the MFU reticle optimizer 220 include layout optimization, cost efficiency, process compatibility, flexibility and scalability, and performance optimization. The benefits of using the MFU reticle optimizer 220 include at least increased efficiency, enhanced flexibility, improved yield, cost savings, and shortened time-to-market. By optimizing the reticle layout, manufacturers can maximize yield, reduce costs, and improve overall production efficiency.

Determining the optimal chiplet size 212 involves interconnect considerations, such as, e.g., interconnect density, latency, and bandwidth. Interconnect density relates to evaluating the density and complexity of interconnects required between chiplets. Higher density interconnects may necessitate smaller, more numerous chiplets. Latency and bandwidth relate to ensuring that the interconnects can meet the latency and bandwidth requirements of the application. Determining the optimal chiplet size 212 further involves manufacturing constraints, such as process technology, defect density, and packaging technology. Process technology relates to considering the process technology nodes available and their implications on yield and cost. Defect density relates to producing smaller chiplets that might be less susceptible to defects, potentially improving yield. Packaging technology relates to evaluating the capabilities and limitations of the packaging technology, such as 2.5D interposers or 3D stacking. Determining the optimal chiplet size 212 further involves taking into consideration iterative optimization results, validation results, and prototyping results. Determining the optimal chiplet size 212 involves balancing multiple factors to achieve the best performance, power efficiency, cost, and manufacturability for a given application. The optimal chiplet size 212 is determined by defining various requirements and constraints pertaining to performance, power, area, cost, and thermal considerations. Performance parameters may include processing power, bandwidth, and latency considerations. Power parameters may include power budget and efficiency considerations. Area parameters may include physical size constraints of the end product. Cost parameters may include estimated cost targets, including development costs and production costs. Thermal considerations may include thermal management capabilities and heat dissipation requirements. The optimal chiplet size 212 is further determined based on functionality and interdependencies. The functionality pertains to breaking down the overall system functionality into smaller, modular blocks that can be implemented as individual chiplets. Interdependencies identify interdependency and communication requirements between the chiplets.

Therefore, determining the optimal chiplet size 212 involves consideration a number of parameters or variables that may be company specific. These parameters may be referred to as a plurality of first parameters.

The optimal chip module size 214 is generated using, e.g., a chip module unit (CMU) chip module optimizer 230. The CMU chip module optimizer 230 is a tool used in semiconductor design and manufacturing processes to optimize the integration and performance of chiplets within a multi-chip module (MCM) or system-in-package (SiP). The primary objective of the CMU chip module optimizer 230 is to enhance the overall performance, power efficiency, and reliability of the final product, while minimizing costs and development time. The main functions of the CMU chip module optimizer 230 include chiplet placement optimization, power and thermal management, signal integrity and timing analysis, design rule checking (DRC) and verification, and cost and manufacturability optimization. The benefits of using the CMU chip module optimizer 230 include at least enhanced performance, power efficiency, reduced development time, cost efficiency, and improved reliability.

Determining the optimal chip module size 214 involves a multi-faceted approach that takes into account at least performance, power efficiency, thermal management, size constraints, cost, and manufacturability. Determining the optimal chip module size 214 involves defining system requirements related to performance, power, thermal considerations, size constraints, and cost. Performance parameters may include determining computational, memory, and input/output (I/O) requirements. Power parameters may include establishing the power budget and efficiency goals. Thermal considerations may include defining thermal constraints and cooling solutions. Size constraints may include identifying physical size limitations based on the final application. Cost parameters may include setting cost targets, including development costs and production expenses, and taking into account manufacturing considerations.

The example embodiments use the MFU reticle optimizer 220 to optimize the chiplet size and the CMU chip module optimizer 230 to optimize the chip module size. This optimization generates an optimized floorplan 240. The optimized floorplan 240 is incorporated onto a wafer 250, which includes a plurality of dies each including the optimized floorplan 240. The MFU reticle optimizer 220 and the CMU chip module optimizer 230 may use company-specific data or information (e.g., AMD data). The AMD data may be historical AMD data for different chiplets of various sizes and orientations. Additionally, the CMU chip module optimizer 230 may be referred to as package chip module circuitry and the MFU reticle optimizer 220 may be referred to as MFU reticle circuitry. The package chip module form, fit, and function, and the MFU of the chiplet size, are boundary conditions that are considered when producing a market leading IC. The IC is an electronic device made of multiple interconnected electronic components and circuitry.

The chiplet optimization tool kit 200, using starting inputs from all the various parameters, will leverage AMD design rules and industry best practices to take a holistic approach and create or generate the optimal floorplan. This approach solves many issues, such as providing a reasonable starting point for architecture planning, reducing the human factor in the system, and streamlining decision alignment.

The process may commence by having a model that shows a user the various trade-offs between chiplet size and chip module size. As such, the architects get an early look at the impact of die size changes, which cuts down on wasted effort. This will decrease the time it takes to bring a cost-effective product to the market. Next, by having a model that is built to leverage the current design rules, the model may reduce re-work, speed up design velocity, and help simplify the floor planning process by relaxing the requirements on subject matter expertise to guide the design to a correct solution. Furthermore, this approach greatly streamlines decision alignment when all stakeholders involved are using the same models and methodologies. That is, time is saved that would otherwise be spent on ensuring that everyone's assumptions going into the execution are the same. As a result, the chiplet optimization tool kit 200 is a robust model that leverages industry leading AI/ML algorithms uniquely paired with ECAD design rule checking engines to produce a holistic approach to selecting an optimized advanced packaging floorplan that will reduce product cost.

The chiplet optimization tool kit 200 may employ AI/ML models or algorithms.

AI/ML models are computational algorithms or mathematical frameworks that enable machines to learn from data and make predictions or decisions without explicit programming. These models form the foundation of various AI applications and systems, ranging from image recognition and natural language processing to autonomous vehicles and recommendation systems.

The main components of AI/ML models include data, features, algorithms, training, evaluation, and inference.

AI/ML models rely on data to learn patterns, relationships, and insights. The quality, quantity, and diversity of data significantly impact the performance and effectiveness of the model. Features are the input variables or attributes extracted from the data that the model uses to make predictions or classifications. Feature engineering involves selecting, transforming, and preprocessing relevant features to improve model accuracy. Machine learning algorithms are mathematical techniques or procedures used to train AI models on data and optimize their parameters to minimize errors or maximize performance. Common ML algorithms include linear regression, decision trees, support vector machines, and neural networks.

Model training involves feeding labeled data (i.e., training data or training examples) into the algorithm and adjusting the model's parameters iteratively to minimize the difference between predicted outputs and actual outputs. Training typically involves techniques such as gradient descent and backpropagation for optimizing parameters. Once trained, the AI/ML models are evaluated on a separate dataset (validation or test set) to assess their performance, generalization ability, and accuracy. Metrics such as accuracy, precision, recall, and area under the curve (AUC) are commonly used to evaluate model performance.

Inference is the process of using a trained model to make predictions or classifications on new, unseen data. During inference, the model applies the learned patterns to new inputs and generates predictions or outputs.

The example embodiments may use any types of AI/ML models. For example, the models may include supervised learning, unsupervised learning, reinforcement learning, deep learning, and/or transfer learning.

In supervised learning, the model is trained on labeled data, where each input example is associated with a corresponding target or output. The model learns to map inputs to outputs and can make predictions on unseen data. Examples include classification and regression tasks.

Unsupervised learning involves training the model on unlabeled data to identify patterns, clusters, or structures within the data. The model learns to uncover hidden relationships or groupings without explicit guidance. Examples include clustering, dimensionality reduction, and anomaly detection.

Reinforcement learning (RL) involves training an agent to interact with an environment and learn optimal actions or policies to maximize cumulative rewards. RL algorithms learn through trial and error, receiving feedback from the environment based on actions taken.

Deep learning is a subset of machine learning that uses artificial neural networks with multiple layers (deep architectures) to learn complex patterns from data. Deep learning excels in tasks such as generative modeling.

Transfer learning involves leveraging knowledge or features learned from one task or domain to improve performance on a related task or domain. Pre-trained models are fine-tuned or adapted to new datasets or tasks with limited labeled data.

Any of these types of AI/ML models may be used by the chiplet optimization tool kit 200 to generate the optimized floorplan 240. The training data may include AMD data or AMD historical data related to a number of variables or parameters. The AMD historical data may include at least information related to die reticle size, chiplet module size, and gross modules per wafer. The training data can further include past chiplet sizes, chiplet orientations, design rules unique to AMD historical data, connectivity between chiplets, ECAD design checking engine parameters, etc. Moreover, weights can be assigned to the training data, enabling users to provide a measure of importance to each. In addition, weights may be assigned to the various factors in the co-optimization subroutine, enabling the toolkit to find different optima based on the use-case and target market for a package design.

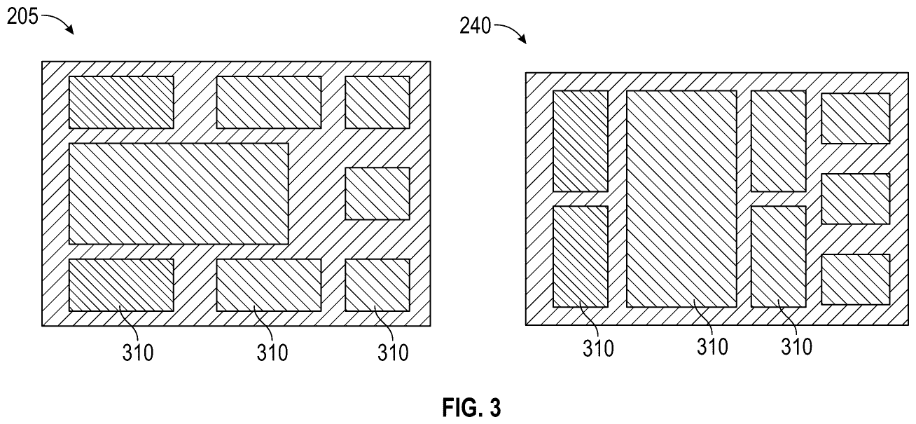

FIG. 3 illustrates how optimizing a chiplet layout produces cost savings, according to an example.

By employing the chiplet optimization tool kit 200, the initial design 205 can be transformed into the optimized floorplan 240. For example, the chiplets 310 are shown in a first layout configuration in the initial design 205. After applying the chiplet optimization tool kit 200, the chiplets 310 are shown in a second layout configuration in the optimized floorplan 240. By optimizing the layout or floorplan, the production process becomes more efficient, thus leading to higher throughput and lower costs. By optimizing the layout or floorplan, the number of usable chips per wafer may be maximized, thus enhancing overall yield and reducing waste. Additionally, by optimizing the layout or floorplan, significant cost savings can be achieved, as the number of mask changes is reduced and the utilization of expensive reticle space is improved, thus leading to significant cost savings in the manufacturing process. Further, by streamlining the reticle design process, faster iteration and quicker time-to-market for new semiconductor products may be achieved. Optimizing the layout or floorplan thus results in optimized material usage, improved power delivery and thermal management, and ensures robust design practices.

In one example, if optimizing the floorplan increases yield by 5%, and each wafer costs $10,000, producing 100 wafers results in a potential savings of $50,000 by yielding more functional chips. Reducing power consumption by 10% across millions of units can lead to substantial operational savings for customers, enhancing the product's value proposition. Savings from reduced cooling requirements can amount to hundreds of dollars per unit, especially in high-performance applications like data centers. Reducing design iterations can save hundreds of hours of engineering time, which can translate into tens of thousands of dollars in labor costs. Thus, generating an optimized or optimal floorplan can result in significant cost savings.

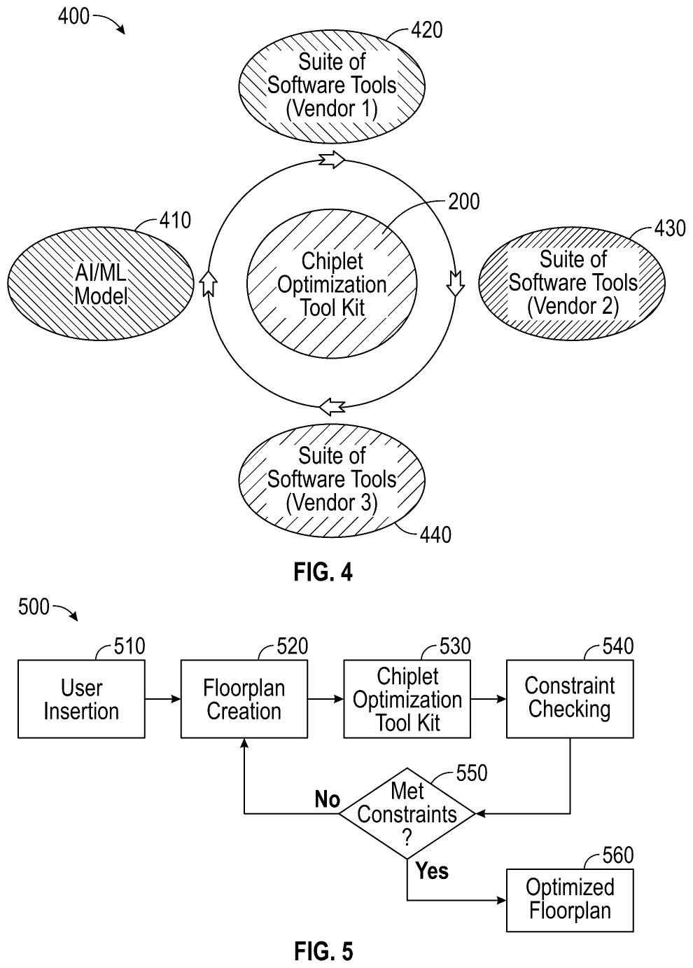

FIG. 4 illustrates interoperability 400 of the chiplet optimization tool, according to an example.

The chiplet optimization tool kit 200 can be employed using any AI/ML model 410. Moreover, the chiplet optimization tool kit 200 may be operable or compatible with any ECAD tools on the market. An ECAD tool is a software application used by engineers to design and develop electronic systems, such as printed circuit boards (PCBs), ICs, and other electronic components. These tools assist in creating schematics, simulating circuit behavior, and generating layouts for manufacturing. ECAD tools are beneficial in ensuring that electronic designs are accurate, reliable, and manufacturable.

The chiplet optimization tool kit 200 may be compatible with, e.g., a first suite of software tools provided by a first vendor 420, a second suite of software tools provided by a second vendor 430, and a third suite of software tools provided by a third vendor 440. The first vendor 420 may provide, e.g., the Siemens Calibre suite of software, the second vendor 430 may provide, e.g., the Synposys 3DIC ICC2 suite of software, and the third vendor 440 may provide, e.g., the Cadence Innovus Cerebrus suite of software. Such software provides a comprehensive suite of electronic design automation (EDA) tools used for the physical verification, design for manufacturability (DFM), and resolution enhancement techniques (RET) of ICs. Such software is used in the semiconductor industry to ensure that IC designs are manufacturable, meet design rules, and perform reliably.

The chiplet optimization tool kit 200 may be compatible with any suite of software developed by any company. The chiplet optimization tool kit 200 can interoperate with any suite of software as it will provide standard file formats and library compatibility. Most EDA tools support standard file formats for layout and design data. This allows for easy exchange of data of design information between the software tools on the market and the chiplet optimization tool kit 200. Further, design libraries, including technology files (or tech files), standard cell libraries, and IP blocks may be shared across these tools to ensure consistency and compatibility. The chiplet optimization tool kit 200 can provide for seamless transition of such data to allow designers to optimize their workflows, improve design quality, and reduce time-to-market.

FIG. 5 illustrates a block diagram of the features of the chiplet optimization tool, according to an example.

The chiplet optimization tool kit 200 includes several novel features and is implemented through a custom methodology. One novel feature is the chiplet optimizer tool kit's bridge between ECAD software and AI/ML models 410. By having a model agnostic bridge, the chiplet optimization tool kit 200 can leverage any AI/ML model 410 and isn't limited by a given model's limitations as technology advances. The model may connect into any industry leading ECAD tool and leverage industry standard design rule engines and rule checks.

Another novel feature relates to integrating the boundary conditions of the problem into the ECAD tool, which enables decoupling all aspects of the optimization problem that are specific to silicon design from aspects specific to AI model training. With this approach, the model does not need to be hard coded to understand the boundary conditions or locked into only a specific packaging technology.

Another novel feature relates to how the model utilizes a distinctive user interface to generate the tech file that houses the design rules to be consumed by the ECAD DRC engine to check the design specific boundary conditions. When a user selects the packaging technology or architecture that will be used in each floorplan, the model generates a design rule technology file that serves as an input to the ECAD tool to assess violations in the floorplan. This technology file creation is useful for this novel feature to work properly and the model to receive the proper training guidelines.

Another novel feature relates to the training weights that are assigned to the modified objective function as the model solves for an optimized floorplan. The weights are based on AMD product design rules, design for manufacturability rules, and design for yield data. For example, one parameter may be assigned a weight of 0.1 (not as critical) and another parameter may be assigned a weight of 0.6 (more critical). The weights may be assigned by designers or engineers based on their expertise and/or prior experience.

The model implements the chiplet optimization tool kit 200 with a novel input/output methodology. The input may be real product data (e.g., chiplet size, orientation/design rule checks, yield, performance metrics, connectivity between chiplets, ECAD design checking engines, de-coupled design and algorithm boundary conditions, and innovative ways of assigning weight functions from the training data. Thus, the design rules and the algorithm boundary conditions are de-coupled, so that they are not hard coded. A feedback loop is provided to feed back the results to the training data and update the training data. As such, the training data is continuously updated, in real-time, so that the chiplet optimization tool kit 200 goes through multiple iterations until a best floorplan solution is obtained. In other words, the first floorplan created is not always the most optimized floorplan. Instead, the chiplet optimization tool kit 200 can go through several iterations until the best or most optimal floorplan solution is created or generated or derived.

The output may be an optimized floorplan, based on optimized gross modules per wafer, optimized chiplet size to maximize yield, and optimized die reticle utilization.

The term “die reticle size” typically refers to the size of the reticle used in semiconductor manufacturing to pattern a single die or chip onto a semiconductor wafer during the lithography process. In other words, the die reticle size represents the area on the reticle that corresponds to one individual semiconductor die.

The die reticle size defines the boundary within which the circuitry of a single semiconductor die is patterned onto the wafer. The die reticle size determines the maximum size of the die that can be manufactured using that reticle. The die reticle size is closely related to the critical dimensions of the semiconductor process technology being used. Critical dimensions refer to the smallest features that can be reliably patterned onto the wafer, such as the width of metal lines or the size of transistors. As semiconductor technology advances and feature sizes shrink, the die reticle size typically decreases to accommodate smaller features and allow for denser packing of transistors and interconnects on the die. Die reticle size influences the productivity of semiconductor manufacturing. Larger reticles can pattern more dies on a single wafer, leading to higher throughput and lower manufacturing costs per die. The choice of die reticle size is influenced by economic factors such as wafer costs, lithography tool capabilities, and market demand for different chip sizes. Common die reticle sizes for leading-edge semiconductor processes may range from several millimeters to tens of millimeters in width and height, representing the area of a single die on the reticle.

“Gross modules per wafer” typically refers to the total number of individual semiconductor modules or chips that can be produced on a single wafer during the semiconductor manufacturing process. Gross modules per wafer is a measure of manufacturing efficiency and productivity, providing insight into the capacity of a semiconductor fabrication facility (fab) and the cost-effectiveness of wafer processing.

The gross modules per wafer metric accounts for the total number of usable semiconductor modules that can be obtained from a single wafer after completing the fabrication process. It includes both functional and defect-free modules. The number of modules per wafer depends on various factors, including the size of the individual semiconductor die or module, the diameter of the semiconductor wafer, and the process technology used for fabrication. The arrangement of individual modules on the wafer, including the spacing between adjacent dies, impacts the number of modules that can fit on a wafer. Design rules and process constraints influence die-to-die spacing and packing density. Gross modules per wafer is a useful factor in determining the cost structure of semiconductor manufacturing. Gross modules per influences wafer pricing, fabrication costs, and ultimately, the cost competitiveness of semiconductor products.

The term “chip module size” typically refers to the physical dimensions or size specifications of an individual semiconductor chip module within an IC package. Chip module size describes the dimensions of the semiconductor die, as well as any additional packaging components or structures that may be included in the module.

The primary component of a chip module is the semiconductor die, which contains the active circuitry, such as transistors, logic gates, and memory cells. Die size is typically measured in terms of length and width, often expressed in millimeters (mm) or micrometers (μm). In addition to the semiconductor die, the chip module may include packaging materials, such as the substrate, encapsulation, and solder balls or pads for connection to the PCB. The overall size of the chip module includes the dimensions of these packaging components. The form factor of the chip module refers to its physical shape and dimensions. Common form factors for semiconductor packages include ball grid array (BGA), quad flat package (QFP), and small outline integrated circuit (SOIC), among others. The thickness of the chip module, measured from the top of the die to the bottom of the package, is also a useful dimension. Thicker modules may demand additional space on the PCB and can impact overall system design and integration. Advances in semiconductor manufacturing technology allow for the fabrication of smaller and more densely packed semiconductor dies. Higher integration density enables smaller chip modules with reduced form factors.

The process 500 can include a user insertion block 510, a floorplan creation block 520, the chiplet optimization tool kit 200, and a constraint checking block 540. At block 550, it is determined whether the constraints have been met. If YES, an optimized floorplan 560 is generated. If NO, the process proceeds back to the floorplan creation block 520. The user insertion block 510 may include a user interface for inputting relevant die attribute data. The floorplan creation block 520 is a chiplet module optimizer that automatically creates scripts to generate floorplan and rule checking files. The constraint checking block 540 includes proprietary design rules used to create technology files.

The advantages of using the chiplet optimization tool kit 200 include at least, by leveraging a model that takes a holistic systematic view to floorplan optimization, reducing the amount of back and forth between subject matter experts. This also helps to enumerate the trade-offs between floorplan choices so that the weighting of each decision can be clearly understood. By creating a standard process driven through a model, the risk of human error is removed from the equation. This will lead to higher quality decisions and less chances of misses due to miscommunication, knowledge gaps, and group oversights. Further, the main objective is to reduce the overall size of the chip module with considerations towards die reticle size, gross modules per wafer, and chiplet arrangements. This will lead to lower production costs and increase the gross margins on products. Lastly, using the chiplet optimization tool kit 200 will lead to faster product time to market as architects will align on the ideal floorplan earlier in the design cycle.

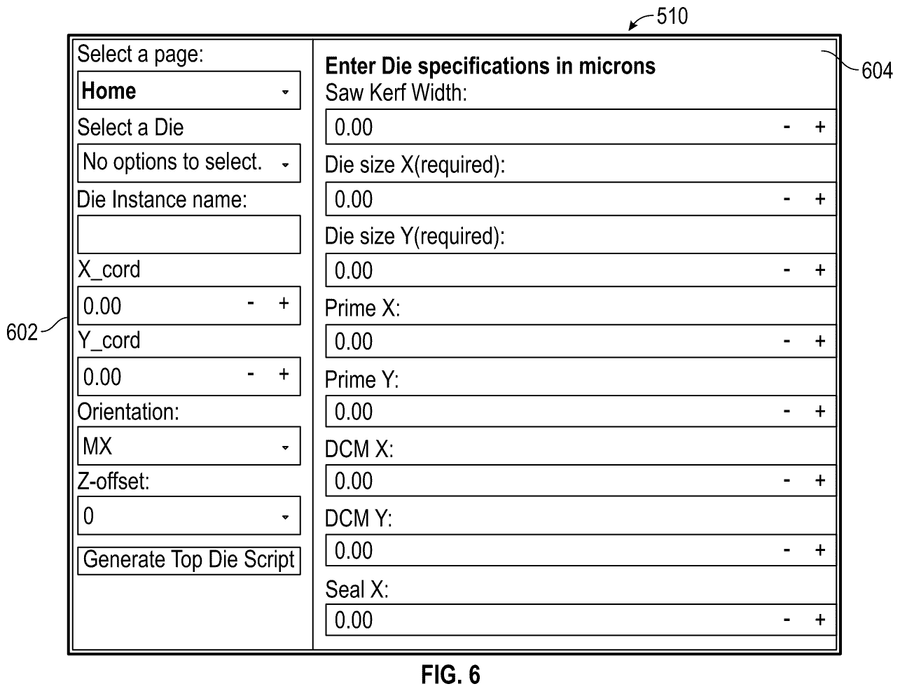

FIG. 6 illustrates a user interface for implementing the chiplet optimization tool, according to an example.

The user interface 610 includes a first area 602 and a second area 604. The first area 602 may be used to enter data or information related to a die. The second area 604 may be used to enter data or information related to die specifications. The user interface 610 may be configured in any manner to accept any type of data or information that may be useful or beneficial for efficiently implementing the chiplet optimization tool kit 200. The data or information can include, but is not limited to, desired manufacturing yield, die size, wafer diameter, die-to-die spacing, process technology, mask alignment and lithography process parameters or variables, package size, form factor, thickness of the chip module, etc.

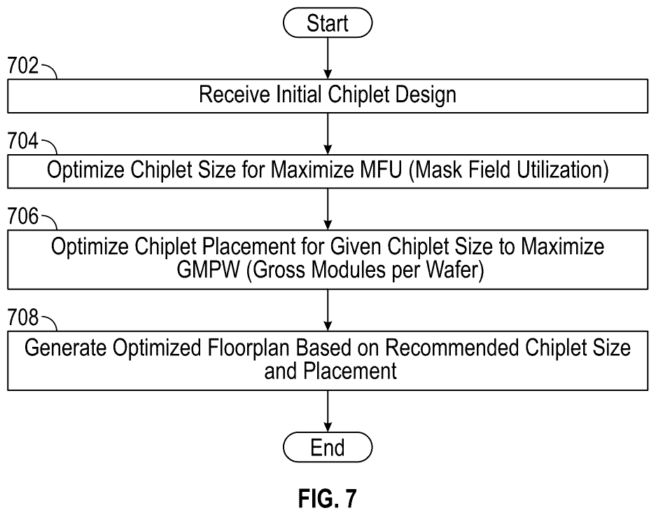

FIG. 7 illustrates a method for implementing the chiplet optimization tool, according to an example.

At block 702, an initial chiplet design is received.

At block 704, the chiplet size is optimized for maximum mask field utilization (MFU). Mask field utilization refers to how efficiently the available area on a photomask is used during the semiconductor manufacturing process. High mask field utilization means that a larger percentage of the photomask area is occupied by the circuit patterns of the chiplets.

At block 706, the chiplet placement is optimized for a given chiplet size to maximize gross modules per wafer (GMPW). The chiplet optimization tool kit 200 automatically optimizes the chiplet placement based on predefined criteria.

At block 708, an optimized floorplan is generated based on the recommended chiplet size and placement.

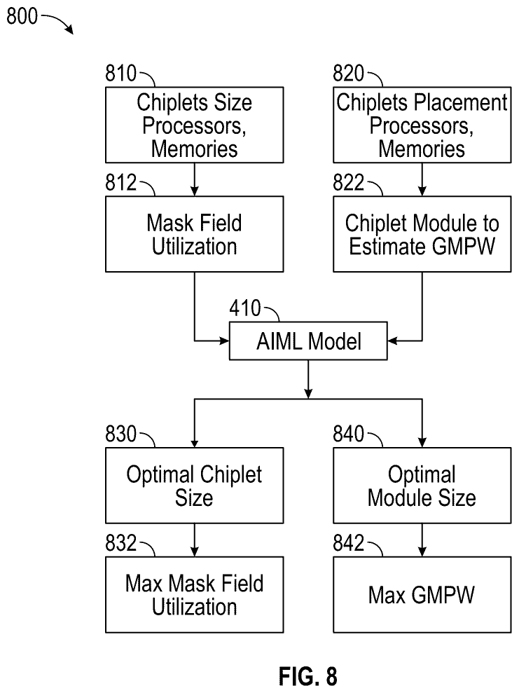

FIG. 8 illustrates a process 800 for generating an optimized floorplan based on optimal chiplet size and optimal module size.

At block 810, chiplet sizes are determined.

At block 812, the chiplet sizes are determined taking MFU into account. MFU refers to how efficiently the available area on a photomask is used during the semiconductor manufacturing process. High mask field utilization means that a larger percentage of the photomask area is occupied by the circuit patterns of the chiplets.

At block 820, chiplet placement is determined.

At block 822, the chiplet placement is determined based on GMPW. GMPW refers to how many chiplets fit onto a chip module that is produced on a wafer. By implementing such strategies, manufacturers may increase the number of usable chip modules per wafer, enhancing yield and reducing cost.

The AI/ML model 410 receives the MFU data and the GMPW data to generate an optimized floorplan. The optimized floorplan is generated from the optimal chiplet size 830 determined from the maximum MFU 832 and the optimal module size 840 determined from the maximum GMPW 842.

In conclusion, a chiplet optimization tool is presented to provide significant cost efficiencies and savings in several key areas of semiconductor design and manufacturing. Optimizing the chiplet floorplan can lead to enhanced yield and reduced waste. By optimizing the placement of chiplets within the package, designers can minimize unused silicon areas, leading to higher yield per wafer. Optimized floorplans reduce the likelihood of defects impacting multiple critical areas, improving overall yield. Efficient floor planning can include redundant paths or components that can be activated if primary ones fail, increasing the number of functional chips per wafer. Optimizing the chiplet floorplan can lead to improved performance and power efficiency. Shorter interconnects lower resistive and capacitive losses, improving performance and reducing power consumption, which can result in lower operational costs for end users. Optimized power delivery networks reduce voltage drops and power losses, enhancing overall efficiency and potentially reducing the need for expensive power management solutions. Optimizing the chiplet floorplan can lead to better thermal management. Proper placement of chiplets helps in spreading out heat generation evenly, reducing the need for complex and costly cooling solutions. Effective thermal management can further reduce the reliance on expensive materials like high-performance thermal interface materials or advanced heat sinks. Optimizing the chiplet floorplan can lead to manufacturing and process optimization. Efficient floorplans can decrease the number of photomasks needed, lowering the cost associated with mask creation and changes during the photolithography process. Floorplans that align well with existing manufacturing processes can avoid the need for expensive modifications or additional processing steps.

Moreover, optimizing the chiplet floorplan can lead to design and development efficiency. Using advanced tools for floor planning can automate many aspects of the design process, reducing the time and labor costs associated with manual design iterations. Optimized layouts are less prone to design errors that can cause costly rework or redesigns. Optimizing the chiplet floorplan can further lead to material and component cost savings. Efficient chiplet placement reduces waste of packaging materials and can optimize the use of interposers or substrates. Optimized floorplans that use standardized chiplets can benefit from economies of scale, reducing the cost per unit of each chiplet. Optimizing the chiplet floorplan can further lead to supply chain and inventory management efficiencies. By optimizing the chiplet floorplan, the need for a variety of different components is reduced, simplifying inventory management and lowering storage costs. An optimized floorplan allows for easier scaling of production volumes, leading to cost savings through bulk purchasing and streamlined logistics.

The example embodiments provide for a chiplet optimization tool using AI/MI models or algorithms in combination with AMD specific data or information to produce optimized chiplet layouts. The AMD specific information may include at least data or information related to the die reticle size, the gross modules per wafer, and the chiplet arrangement. The novel features include at least providing a bridge between the ECAD and the AI/ML model, accepting boundary conditions specific to a design de-coupled from the AI model and AI training, a user interface for capturing the relevant die attribute data, and a weight function or training weights assigned to the modified objective function as the AI model creates the optimized floorplan.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A system comprising:
at least one physical processor; and
physical memory comprising computer-executable instructions that, when executed by the physical processor, cause the physical processor to:
receive an initial chiplet layout;
determine chiplet size for improving mask field utilization (MFU) using a plurality of first parameters;
determine chiplet placement for improving gross modules per wafer (GMPW) using a plurality of second parameters; and
generate an updated chiplet floorplan based on the determined chiplet size and the determined chiplet placement.

2. The system of claim 1, wherein machine learning (ML) models are used to generate the updated chiplet floorplan.

3. The system of claim 2, wherein the ML models use training data derived from at least one of design rules, electronic computer-aided design (ECAD) tools, technology generation files, and a weight assigned to each of the plurality of first parameters and the plurality of second parameters.

4. The system of claim 1, wherein the plurality of first parameters and the plurality of second parameters are derived from data pertaining to die reticle size, chiplet module size, and gross modules per wafer.

5. The system of claim 1, wherein the plurality of first parameters and the plurality of second parameters include at least one of performance parameters, power parameters, area parameters, thermal parameters, and cost parameters.

6. The system of claim 5, wherein the plurality of first parameters and the plurality of second parameters include at least one of interconnect considerations, manufacturing constraints, iterative optimization data, testing data, and prototyping data.

7. The system of claim 1, wherein a chiplet floorplan user interface is employed to input the plurality of first parameters and the plurality of second parameters.

8. The system of claim 1, wherein weights are assigned to each of the plurality of first parameters and each of the plurality of second parameters based on training data applied to ML models.

9. A non-transitory computer-readable medium storing instructions that, when executed by a processor, cause the processor to:
receive an initial chiplet layout;
determine chiplet size for improving mask field utilization (MFU) using a plurality of first parameters;
determine chiplet placement for improving gross modules per wafer (GMPW) using a plurality of second parameters; and
generate an updated chiplet floorplan based on the determined chiplet size and the determined chiplet placement.

10. The non-transitory computer-readable medium of claim 9, wherein machine learning (ML) models are used to generate the updated chiplet floorplan.

11. The non-transitory computer-readable medium of claim 10, wherein the ML models use training data derived from at least one of design rules, electronic computer-aided design (ECAD) tools, technology generation files, and a weight assigned to each of the plurality of first parameters and the plurality of second parameters.

12. The non-transitory computer-readable medium of claim 9, wherein the plurality of first parameters and the plurality of second parameters are derived from data pertaining to die reticle size, chiplet module size, and gross modules per wafer.

13. The non-transitory computer-readable medium of claim 9, wherein the plurality of first parameters and the plurality of second parameters include at least one of performance parameters, power parameters, area parameters, thermal parameters, and cost parameters.

14. The non-transitory computer-readable medium of claim 13, wherein the plurality of first parameters and the plurality of second parameters include at least one of interconnect considerations, manufacturing constraints, iterative optimization data, testing data, and prototyping data.

15. The non-transitory computer-readable medium of claim 9, wherein weights are assigned to each of the plurality of first parameters and each of the plurality of second parameters based on training data applied to ML models.

16. A method for modifying a chiplet floorplan, the method comprising:
receiving an initial chiplet layout;
determining chiplet size for improving mask field utilization (MFU) using a plurality of first parameters;
determining chiplet placement for improving gross modules per wafer (GMPW) using a plurality of second parameters; and
generating an updated chiplet floorplan based on the determined chiplet size and the determined chiplet placement.

17. The method of claim 16, wherein machine learning (ML) models are used to generate the updated chiplet floorplan.

18. The method of claim 17, wherein the ML models use training data derived from at least one of design rules, electronic computer-aided design (ECAD) tools, technology generation files, and a weight assigned to each of the plurality of first parameters and the plurality of second parameters.

19. The method of claim 16, wherein the plurality of first parameters and the plurality of second parameters are derived from data pertaining to die reticle size, chiplet module size, and gross modules per wafer.

20. The method of claim 16, wherein the plurality of first parameters and the plurality of second parameters include at least one of performance parameters, power parameters, area parameters, thermal parameters, and cost parameters.
